(19) United States
(12) Patent Application Publication
(10) Pub. No.: US 2024/0290708 A1
(43) Pub. Date: Aug. 29, 2024

(54) SUBSTRATE-ON-FOIL WITH METAL PATTERNED COMPONENTS FORMED THEREIN AND METHOD OF MAKING THE SAME

(71) Applicant: Lux Semiconductors, Inc., Albany, NY (US)

(72) Inventors: Chad B. MOORE, Albany, NY (US); Graeme HOUSSER, Albany, NY (US); Shane McMAHON, Albany, NY (US)

(73) Assignee: Lux Semiconductors, Inc., Albany, NY (US)

(21) Appl. No.: 18/590,190

(22) Filed: Feb. 28, 2024

Related U.S. Application Data
(60) Provisional application No. 63/487,345, filed on Feb. 28, 2023.

(51) Int. Cl. H01L 23/498; G03F 7/00; H01L 21/48; H05K 1/05; H05K 3/44

(52) U.S. Cl. CPC H01L 23/49838; G03F 7/0035; H01L 21/4828; H01L 23/49827; H05K 1/05; H05K 3/44

(57) ABSTRACT

A substrate-on-foil formed of a metal substrate core metal including patterned metal in-substrate structures therein which are of a different metal than the metal in which the metal substrate core is formed, with the patterned in-substrate structures being isolated from the metal substrate core by a dielectric material, and methods of making the same.

### STATEMENT REGARDING FEDERALLY SPONSORED RESEARCH OR DEVELOPMENT

Not applicable.

### COPYRIGHT NOTICE

A portion of this disclosure contains material which is subject to copyright protection. The copyright owner has no objection to the photocopy reproduction by anyone of the patent document or the patent disclosure in exactly the form it appears in the Patent and Trademark Office patent file or records, but otherwise reserves all copyright rights whatsoever. 37 C.F.R 1.71(d).

### REFERENCE TO RELATED APPLICATIONS

This application claims the benefit of Provisional Application No. 63/487,345, filed Feb. 28, 2023, entitled “SYSTEM ON FOIL.” The benefit under 35 USC § 119(e) of the United States provisional application is hereby claimed, and the aforementioned provisional application is hereby incorporated herein by reference in its entirety.

### BACKGROUND OF THE INVENTIVE CONCEPT

### 1. Field of the Invention

The present inventive concept relates to a substrate-on-foil formed of a metal substrate core including metal patterned in-substrate structures formed therein, and methods of making the same. More particularly, but not exclusively, the present inventive concept relates to a substrate-on-foil formed of a metal substrate core including metal patterned in-substrate structures formed therein which are different metals than the metal in which the metal substrate core is formed, and methods of making the same.

### 2. Description of the Related Art

The high cost of advancing to the next semiconductor technology node (e.g., 5 nm) is changing the role of packaging in the electronics industry. With each new node, Moore's Law has historically fulfilled the economic and technological promises of density, speed, power, and cost scaling. However, these benefits are now slowing, and new packaging solutions are needed to maintain the pace of economic advantages previously met with silicon scaling.

Conductive through substrate vias are required for nearly all advanced packaging applications since successfully partitioning a System-on-Chip (SoC) design requires an abundance of Inputs/Outputs (I/Os). This is because SoC designs comprise millions of logic gates connected by complex networks of wires, in the form of multiple buses, complicated clock distribution networks, and control signals. Standard device I/Os impose pin-to-pin delays that degrade overall circuit performance. Moreover, using time-domain multiplexing (TDM) on standard I/Os to increase the virtual pin count by running multiple signals on each I/O imposes even greater latencies that can slow I/O speeds down by a factor of 4×-32× or more. TDM approaches also result in higher power consumption. When used to drive hundreds of package-to-package connections across PCB traces between multiple chips, standard device I/O pins carry a heavy power penalty compared to connecting logic nets on a monolithic die. These requirements all lead to a demand for vias through the substrate.

There are presently three options to achieve a feedthrough within an electronic substrate: Through Panel Vias (TPVs)—electrical conduits through printed circuit boards or organic substrates; Through Silicon Vias (TSVs)—electrically isolated copper traces through a thinned silicon wafer; and Through Glass Vias (TGVs)—metal filled holes through a glass wafer. All of the processing techniques to create conductive center pins for conductive through vias use electrodeposited copper or a conductive paste screen printing process that uses gold, silver or copper mixed with a glass powder and a polymer binder to form the conductive paste.

One issue with TPVs in printed circuit boards is the minimum resolution of wires (metal lines) and space is limited for larger features. Most printed circuit boards can pattern 4 mil (100 μm) or 3 mil (75 μm) lines and spacing and the state of the art is around 1.2 mil (30 μm), but at a very high premium price. Holes for through panel vias are limited to about 6 mils (150 μm). These large features mostly limit printed circuit boards to packaged components and do not allow for high resolution components, such as flip chip dies. Because of issues with electroplating copper to fill the large drilled holes in the printed circuit boards the TPVs are usually large barrel coated holes with an opening in the center of the via. One example of a TPV is described in U.S. Pat. No. 6,717,071 “Coaxial Via Hole and Process of Fabricating the Same.”

Besides the high cost of TSV, they also have low mechanical strength. Because the silicon interposers are thinned down to create the TSV, they are weak and subject to cracking and breaking. When a silicon interposer package is increased in size and attached to a printed circuit board the coefficient of thermal expansion (CTE) mismatch between the silicon interposer and organic substrate can cause the bonding bumps to physically crack or break. The TSV can also warp, which can prevent fabrication or assembly, leading to phenomenons such as ball grid array (BGA) non-wets.

Through glass vias (TGVs), and to a lesser extent through silicon vias (TSVs), suffer from a lack of their ability to dissipate heat. The glass substrates in TGVs are insulators, thus only allowing heat to escape out of the top of the package. The TGVs are also not flexible, thus limiting their role in certain applications.

System-on-Foil™, detailed in PCT/US20/54245 “System-on-Foil™ Device,” included herein by reference, is a system-level advanced packaging technology designed to address the shortcomings of the current 2.5/3D packaging architecture. Within System-on-Foil™ and all advanced packages, there exists a substrate with multilevel wiring layers to allow surface mounted electronic components to communicate with one another.

However, an issue with using a metal substrate for HI is that larger pads and solder bumps attached to wiring layers on the metal substrate can capacitively couple to the substrate, therefore limiting the high-frequency bandwidth.

U.S. patent application Ser. No. 18/446,841, filed on Aug. 9, 2023 by the same inventors of the present patent application, discloses metal substrates patterned with metal in-substrate structures which are formed of the same body of metal as the metal substrate itself. FIG. 1A illustrates a metal substrate 300 patterned with three different metal in-substrate structures 300m therein, which are formed of the same metal body as the metal substrate 300 itself. FIG. 1B illustrates a metal substrate 400 patterned with a metal in-substrate structure 402 therein, which is formed of the same metal body as the metal substrate 400 itself.

Accordingly, there is a need for metal based package substrates with in-substrate structures formed therein of a dielectric and a different metal, to be able to tailor the electronic properties of the in-substrate metal for the desired performance criteria. Additionally, the selection of type of in-substrate metal allows for different processing parameters, and thus manufacturability and cost considerations.

### SUMMARY OF THE INVENTIVE CONCEPT

The present general inventive concept provides a substrate-on-foil including metal patterned components formed therein, and methods of making the same. More particularly, but not exclusively, the present inventive concept relates to a substrate-on-foil including metal patterned components formed therein which are different metals than the metal in which the substrate if formed, and methods of making the same.

Additional features and utilities of the present general inventive concept will be set forth in part in the description which follows and, in part, will be obvious from the description, or may be learned by practice of the general inventive concept.

The foregoing and/or other features and utilities of the present general inventive concept may be achieved by providing a substrate-on-foil, comprising: a metal substrate core; at least one in-substrate metal structure patterned through the metal substrate core, the at least one in-substrate metal structure consisting of a different type of metal than the metal of the metal substrate core; and a dielectric material completely isolating the at least one in-substrate metal structure from the metal substrate core.

In an exemplary embodiment, the at least one in-substrate metal structure is made of a metal which is more electrically conductive than the core metal.

In another exemplary embodiment, the at least one in-substrate metal structure is made of copper.

In another exemplary embodiment, the dielectric material is selected from a group consisting of: a) a polymer; b) a silicone; c) a glass; d) a ceramic; or any combination of a through d.

In still another exemplary embodiment, the metal substrate core is between 200-400 μm in thickness.

In still another exemplary embodiment, the metal substrate core is between 10-1000 μm in thickness.

The foregoing and/or other features and utilities of the present general inventive concept may also be achieved by providing a method of fabricating a substrate-on-foil, the method comprising: etching at least one three-dimensional trench partially through a metal core structure from a top surface thereof; filling the at least one three-dimensional trench with a photoresist material; etching a trench into the photoresist material; depositing a metal of a different type than the type of metal that the metal core structure consists of into each trench etched into the photoresist material; etching away the photoresist to leave a partial trench surrounding the deposited metal; depositing a dielectric material into the partial trench surrounding the deposited metal; and griding a back side of the metal core structure until the deposited metal and surrounding dielectric material are exposed.

The foregoing and/or other features and utilities of the present general inventive concept may also be achieved by providing a method of fabricating a substrate-on-foil, the method comprising: etching at least one three-dimensional trench partially through a metal core structure from a top surface thereof; filling the at least one three-dimensional trench with a photoresist material; etching a trench into the photoresist material; depositing a metal of a different type than the type of metal the metal of the metal core structure into each trench etched into the photoresist material; etching away the photoresist to leave a trench surrounding the deposited metal; depositing a dielectric material into the trench surrounding the deposited metal; turning the metal core over and performing the steps of: etching at least one three-dimensional trench partially through the back side of the metal core structure to expose the at least one dielectric material and deposited metal; filling the at least one three-dimensional trench with a photoresist material; etching a trench into the photoresist material to expose the deposited metal; depositing a metal of a different type than the type of metal than the metal of the metal substrate into each trench etched into the photoresist material to form a through metal via; etching away the photoresist to leave a partial trench surrounding the deposited metal; and depositing a dielectric material into the partial trench surrounding the deposited metal.

The foregoing and/or other features and utilities of the present general inventive concept may also be achieved by providing a method of fabricating a substrate-on-foil, the method comprising: etching at least one three-dimensional trench partially through a metal core structure from a top surface thereof; filling the at least one three-dimensional trench with a dielectric material; etching a trench into the dielectric material; depositing a metal of a different type than the type of metal that the metal core structure consists of into each trench etched into the dielectric material; and griding a back side of the metal core structure until the deposited metal and surrounding dielectric material are exposed.

The foregoing and/or other features and utilities of the present general inventive concept may also be achieved by providing a method of fabricating a substrate-on-foil, the method comprising: etching at least one three-dimensional trench partially through a metal core structure from a top surface thereof; filling the at least one three-dimensional trench with a dielectric material; etching a trench into the dielectric material; depositing a metal of a different type than the type of metal that the metal core structure consists of into each trench etched into the dielectric material; etching at least one three-dimensional trench through the metal core structure from a back side thereof until the deposited metal and dielectric material are exposed; filling the at least one three-dimensional trench with a dielectric material; etching a trench into the dielectric material until the deposited metal is exposed; and depositing a metal of a different type than the type of metal that the metal core structure consists of into each trench etched into the dielectric material to form a through metal via.

### BRIEF DESCRIPTION OF THE DRAWINGS

These and/or other features and utilities of the present inventive concept will become apparent and more readily appreciated from the following description of the embodiments, taken in conjunction with the accompanying drawings of which:

FIG. 1A illustrates a substrate-on-foil currently patent pending by the current Applicant.

FIG. 1B illustrates another substrate-on-foil currently patent pending by the current Applicant.

FIG. 2 illustrates a substrate-on-foil according to an example embodiment of the present inventive concept.

FIGS. 2A-2I illustrate process steps for fabricating the substrate-on-foil illustrated in FIG. 2.

FIG. 3 illustrates a substrate-on-foil according to another example embodiment of the present inventive concept.

FIGS. 3A-3G illustrate process steps for fabricating the substrate-on-foil illustrated in FIG. 3.

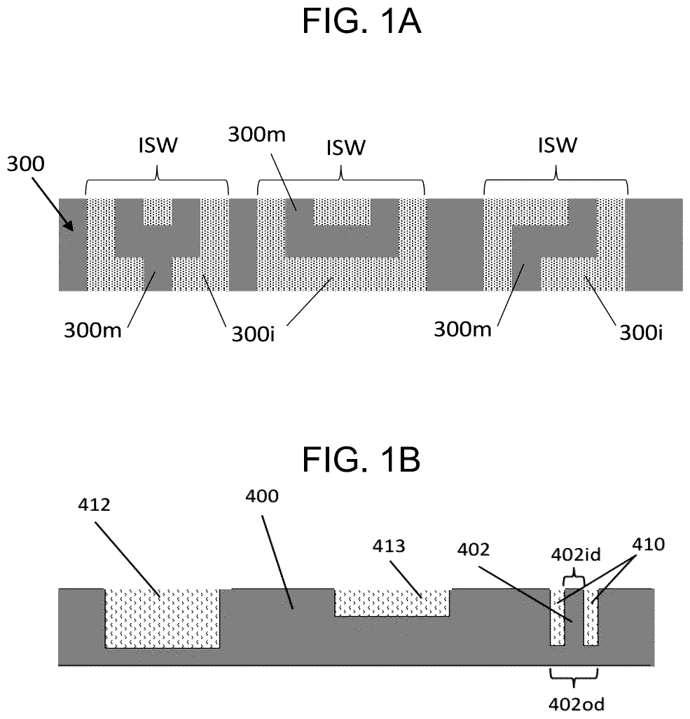

The drawings illustrate a few example embodiments of the present inventive concept and are not to be considered limiting in its scope, as the overall inventive concept may admit to other equally effective embodiments. The elements and features shown in the drawings are to scale and attempt to clearly illustrate the principles of exemplary embodiments of the present inventive concept. In the drawings, reference numerals designate like or corresponding, but not necessarily identical, elements throughout the several views.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures. Also, while describing the present general inventive concept, detailed descriptions about related well-known functions or configurations that may diminish the clarity of the points of the present general inventive concept are omitted.

It will be understood that although the terms “first” and “second” are used herein to describe various elements, these elements should not be limited by these terms. These terms are only used to distinguish one element from another element. Thus, a first element could be termed a second element, and similarly, a second element may be termed a first element without departing from the teachings of this disclosure.

Expressions such as “at least one of,” when preceding a list of elements, modify the entire list of elements and do not modify the individual elements of the list.

All terms including descriptive or technical terms which are used herein should be construed as having meanings that are obvious to one of ordinary skill in the art. However, the terms may have different meanings according to an intention of the inventors, case precedents, or the appearance of new technologies. Also, some terms may be arbitrarily selected by the inventors, and in this case, the meaning of the selected terms will be described in detail in the detailed description herein. Thus, the terms used herein have to be defined based on the generally defined meaning of the terms together with the description throughout this specification.

Hereinafter, one or more exemplary embodiments of the present general inventive concept will be described in detail with reference to accompanying drawings.

Example embodiments of the present general inventive concept are directed to substrates-on-foil which include a metal substrate core and metal component structures patterned within the metal substrate core which are formed of a different metal than the metal core and isolated from the metal substrate core, and methods of making the same.

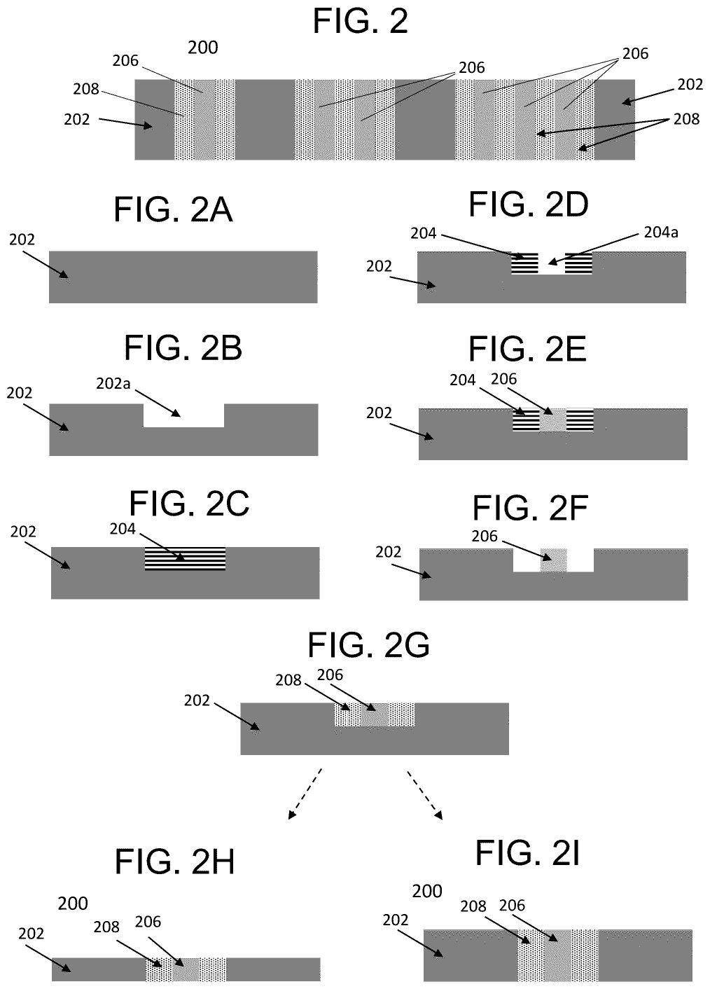

FIG. 2 illustrates a substrate-on-foil 200 according to an example embodiment of the present inventive concept. More specifically, FIG. 2 illustrates a substrate-on-foil 200 comprising a metal core 202 having metal component structures 206 patterned therein which are formed of a different metal than the metal core 202 itself. In accordance with an example embodiment the metal substrate core can be between 10-1000 μm in thickness from a top surface to a back side surface. However, a standard embodiment may have a core thickness between 50-500 μm, and even more narrow still, a core thickness between 100-250 μm from a top surface to a back side surface. The metal component structures 206 can be isolated from the metal core 202 by a dielectric material 208. In accordance with an example embodiment the dielectric material 208 can be formed of silicon dioxide (SiO₂). Alternatively, the dielectric material can be selected from a group consisting of: a) a polymer; b) a silicone; c) a glass; d) a ceramic; or any combination of a through d. The metal substrate can consist of a material selected from a group consisting of: a) Molybdenum; b) Iron; c) Titanium; d) Chromium; e) Tantalum; f) Tungsten; g) Copper; h) Nickel; i) Vanadium; j) Aluminum; k) Cobolt; or any alloy comprised of a) through k).

The metal component structures 206 can be patterned to create any type of in-substrate structure (ISS) desired depending on the ISSs required to complete the semiconductor packages and/or semiconductor boards in which the substrate-on-foil 200 will be integrated with. The metal component structures 206 are preferably formed of copper. However, other types of metals which provide the intended purposes described herein can be used for the metal component structures 206 without departing from the spirit and scope of the overall present inventive concept.

FIGS. 2A-2G illustrate the process steps to fabricate the substrate-on-foil 200 according to the example embodiment illustrated in FIG. 2.

FIG. 2A illustrates a foil or metal substrate 202.

FIG. 2B illustrates a process of etching a trench(es) 202a into the metal substrate 202. The trench(es) 202a can be etched into any three-dimensional (3D) shape. The etching process can be performed by laser ablating through the top of the metal substrate 202 to create the trench(es) 202a partially therethrough.

FIG. 2C illustrates a process of depositing a photoresist 204 into the trench(es) 202a. The photoresist 204 can be deposited into the trench(es) 202a by a spin coating process. However, the photoresist layer 204 can be deposited into the trench(es) 202a by other equivalent deposition processes which will provide the intended purpose of filling the trench 202a with a photoresist 204.

FIG. 2D illustrates a process of etching the deposited photoresist 204. After the photoresist layer 204 is deposited into the trench(es) 202a the photoresist 204 can be partially etched to create another trench(es) 204a which exposes a portion of the top of the metal core 202, as illustrated in FIG. 2D.

FIG. 2E illustrates a process of depositing a metal 206 into the trench(es) 204a formed in the photoresist layer 204. The metal 206 deposited in the trench(es) 204a can be copper, and can be deposited via an electroplating process or other chemical bath process, or a vapor phase process (these methodologies encompass techniques such as chemical vapor deposition (CVD), physical vapor deposition (PVD), atomic layer deposition (ALD), and molecular beam epitaxy (MBE), among others, which allows for flexibility in selecting an appropriate deposition method based on desired material properties, feature geometries, and process compatibility). Alternatively, the metal 206 can be deposited into the trench(es) 204a by other known metal deposition processes which will completely fill the trench(es) 204a.

FIG. 2F illustrates a process of stripping the remaining photoresist 204 from the trench(es) 202a, thus leaving only the metal 206 within the trench(es) 202a. This stripping process can be performed via an etch bath or other known photoresist stripping processes.

Referring to FIG. 2G, the remaining portions of the trench(es) 202a can then be filled with a dielectric material 208 to surround the metal structure 206, thus forming a metal core 202 having a different metal structure(s) 206 formed therein which is surrounded by a dielectric material 208.

FIG. 2H illustrates a process of converting the structure illustrated in FIG. 2G into a substrate-on-foil 200 comprising a metal core 202 having metal component structures 206 patterned therein which are formed of a different metal than the metal core 202 itself and are isolated from the metal core 202, according to an example embodiment of the present inventive concept. In this example embodiment, the metal core 202 structure illustrated in FIG. 2G can be back grinded to expose both the dielectric material 208 and metal patterned structure(s) 206, which are isolated from the metal core 202 by the surrounding dielectric material 208. The process according to this example embodiment will result in a thinner substrate-on-foil 200 than the original metal core 202.

FIG. 2I illustrates a process of converting the structure illustrated in FIG. 2G into a substrate-on-foil 200 comprising a metal core 202 having metal component structures 206 patterned therein, which are formed of a different metal than the metal core 202 itself and are isolated from the metal core 202, according to another example embodiment of the present inventive concept. In this example embodiment, the metal core 202 structure illustrated in FIG. 2G can be flipped over so that the same process described with reference to FIGS. 2A-2G can be performed on the back side of the metal core 202. More specifically, another process of etching a trench(es) into the back side of the metal substrate 202 can be performed such that the newly etched trenches align with the originally formed trenches on the top side of the metal core 202. After the processes described with reference to FIGS. 2A-2G are performed the exact same metal structures 206 and dielectric material 208 will connect with the originally formed metal structures 206 and dielectric material 208 to form a substrate-on-foil 200 with in-substrate metal structures 206 which extend through the metal substrate 202 and are isolated from the metal substrate 202 by dielectric material 208. The substrate-on-foil 200 according to this example embodiment will have the same thickness as the original metal core 202.

It is to be noted that other metal in-substrate structures other than the illustrated coaxial in-substrate structures 206 can be patterned within the metal core 202 by the similar processes as described above with respect to FIG. 2I, but instead of laser ablating and patterning in alignment with the top surface of the metal core 202, different positions of laser ablating and patterning can be performed on the back side of the metal core 202, which will result in non-linear metal in-substrate structures used to form other ISSs such as antennas, wave guides, etc., without departing from the spirit and scope of the overall present inventive concept.

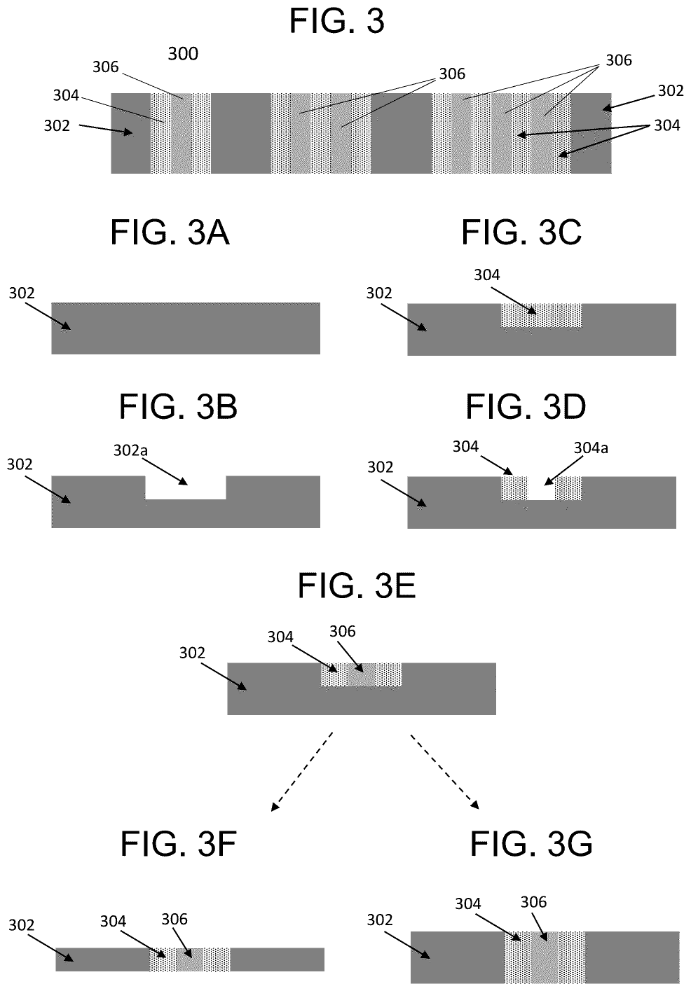

FIG. 3 illustrates a substrate-on-foil 300 according to another example embodiment of the present inventive concept. More specifically, FIG. 3 illustrates a substrate-on-foil 200 comprising a metal core 302 having metal component structures 306 patterned therein which are formed of a different metal than the metal core 302 itself. In accordance with an example embodiment the metal substrate core can be between 10-1000 μm in thickness from a top surface to a back side surface. However, a standard embodiment may have a core thickness between 50-500 μm, and even more narrower still, a core thickness between 100-250 μm from a top surface to a back side surface. The metal component structures 306 are isolated from the metal core 302 by a dielectric material 308. In accordance with an example embodiment the dielectric material 208 can be formed of silicon dioxide (SiO₂). The dielectric material can also be selected from a group consisting of: a) a polymer; b) a silicone; c) a glass; d) a ceramic; or any combination of a through d.]. The word polymer as used herein is intended to include all carbon-based long chain molecules, like thermoplastics and thermosets, and where silicone includes all silicon/oxygen-based molecules. An inorganic material, such as glass, is used as the dielectric material to fabricate a hermetic via. To make the vias truly hermetic, not only will an inorganic dielectric material be required, but the proper bonding between the metal substrate and the dielectric material will have to be achieved, as well as a reasonable CTE match between the metal substrate and the dielectric material. The key property of the dielectric isolation region is to not allow current to flow across the region.

The metal substrate can be from a metal material selected from a group consisting of: a) Molybdenum; b) Iron; c) Titanium; d) Chromium; e) Tantalum; f) Tungsten; g) Copper; h) Nickel; i) Vanadium; j) Aluminum; k) Cobolt; or any alloy comprised of a) through k). One of the most useful metal alloys in the hermetic seal industry is 52 alloy, which consists of 50.5% Ni with a balance of Fe. 52 alloy and usually has a little Chromium to help the bonding to the dielectric insulating glass. The high Nickel content in 52 alloy gives the substrate a low CTE, on the order of 54×10-7/° C. (5.4 ppm/° C.), which makes the substrate a good candidate for the electronic packaging industry. Molybdenum with a CTE of 48×10-7/° C. (4.8 ppm/° C.) at 25° C. and a high thermal conductivity (138 W/m K) makes the substrate an even better candidate for electronic packaging.

The metal component structures 306 can be patterned to create any type of structural form desired depending on the in-substrate structures ISS required for the intended circuitry in which the metal component structures 306 will be integrated with. The metal component structures 306 are preferably formed of copper. However, other types of metals which provide the intended purposes described herein can be used without departing from the spirit and scope of the overall inventive concept.

FIGS. 3A-3G illustrate the process steps to fabricate the substrate-on-foil 300 according to the example embodiment illustrated in FIG. 3.

FIG. 3A illustrates a foil or metal substrate 302.

FIG. 3B illustrates a process of etching a trench(es) 302a into the metal substrate 302. The trench(es) 302a can be etched into any three-dimensional (3D) shape. The etching process can be performed by laser ablating the top of the metal substrate 302 to create the trench(es) 302a partially therethrough.

FIG. 3C illustrates a process of depositing a dielectric material 304 into the trench(es) 302a. The dielectric material 304 can be deposited into the trench(es) 302a by any known dielectric deposition process. The dielectric material 304 can be a silicon dioxide (SiO₂) or other materials having good dielectric properties.

FIG. 3D illustrates a process of etching the dielectric material 304. After the dielectric material 304 is deposited into the trench(es) 302a the dielectric material 304 can be partially etched to create another trench(es) 304a which exposes a portion of the top of the metal core 302, as illustrated in FIG. 3D.

FIG. 3E illustrates a process of depositing a metal 306 into the trench(es) 304a formed in the dielectric material 304. The metal 306 deposited in the trench(es) 304a can be copper, and can be deposited via an electroplating process. Alternatively, the metal 306 can be deposited into the trench(es) 304a by other known metal deposition processes which will completely fill a trench 304a.

FIG. 3F illustrates a process of converting the structure illustrated in FIG. 3E into a substrate-on-foil 300 comprising a metal core 302 having metal component structures 306 patterned therein which are formed of a different metal than the metal core 302 itself and are isolated from the metal core 302, according to an example embodiment of the present inventive concept. In this example embodiment, the metal core 302 structure illustrated in FIG. 3E can be back grinded to expose both the dielectric material 304 and metal patterned structure(s) 306 which are isolated from the metal core 302 by the surrounding dielectric material 304. This example process will result in a thinner substrate-on-foil 300 than the original metal core 302.

FIG. 3G illustrates a process of converting the structure illustrated in FIG. 3E into a substrate-on-foil 300 comprising a metal core 302 having metal component structures 306 patterned therein which are formed of a different metal than the metal core 302 itself and are isolated from the metal core 302, according to another example embodiment of the present inventive concept. In this example embodiment, the metal core 302 structure illustrated in FIG. 3E can be flipped over so that the same process described with reference to FIGS. 3A-3E can be performed on the back side of the metal core 302. More specifically, another process of etching a trench(es) into the back side of the metal substrate 302 can be performed such that the newly etched trenches align with the originally formed trenches on the top side of the metal core 302. After the processes described with reference to FIGS. 3A-3E are performed the exact same structures 306 and dielectric material 304 will connect with the originally formed structures 306 and dielectric material 304 to form a substrate-on-foil 300 having the same thickness as the original metal core 302.

It is to be noted that other metal in-substrate structures other than the illustrated coaxial in-substrate structures 306 can be patterned within the metal core 302 by the similar processes as described above with respect to FIG. 3G, but instead of laser ablating and patterning in alignment with the top surface of the metal core 302, different positions of laser ablating and patterning can be performed on the back side of the metal core 302, which will result in non-linear metal in-substrate structures used to form other ISSs such as antennas, wave guides, etc., without departing from the spirit and scope of the overall present inventive concept. Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A substrate-on-foil, comprising:
a metal substrate core;
at least one in-substrate metal structure patterned through the metal substrate core, the at least one in-substrate metal structure consisting of a different type of metal than the metal of the metal substrate core; and
a dielectric material completely isolating the at least one in-substrate metal structure from the metal substrate core.

2. The substrate-on-foil according to claim 1, wherein the at least one in-substrate metal structure is made of a metal which is more electrically conductive than the core metal.

3. The substrate-on-foil according to claim 2, wherein the at least one in-substrate metal structure is made of copper.

4. The substrate-on-foil according to claim 1, wherein the dielectric material is selected from a group consisting of: a) a polymer; b) a silicone; c) a glass; d) a ceramic; or any combination of a through d.

5. The substrate-on-foil according to claim 1, wherein the metal substrate core is between 10-1000 μm in thickness.

6. A method of fabricating a substrate-on-foil, the method comprising:
etching at least one three-dimensional trench partially through a metal core structure from a top surface thereof;
filling the at least one three-dimensional trench with a photoresist material;
etching a trench into the photoresist material;
depositing a metal of a different type than the type of metal that the metal core structure consists of into each trench etched into the photoresist material;
etching away the photoresist to leave a partial trench surrounding the deposited metal;
depositing a dielectric material into the partial trench surrounding the deposited metal; and
griding a back side of the metal core structure until the deposited metal and surrounding dielectric material are exposed.

7. A method of fabricating a substrate-on-foil, the method comprising:
etching at least one three-dimensional trench partially through a metal core structure from a top surface thereof;
filling the at least one three-dimensional trench with a photoresist material;
etching a trench into the photoresist material;
depositing a metal of a different type than the type of metal the metal of the metal core structure into each trench etched into the photoresist material;
etching away the photoresist to leave a trench surrounding the deposited metal;
depositing a dielectric material into the trench surrounding the deposited metal;
turning the metal core over and performing the steps of:
etching at least one three-dimensional trench partially through the back side of the metal core structure to expose the at least one dielectric material and deposited metal;
filling the at least one three-dimensional trench with a photoresist material;
etching a trench into the photoresist material to expose the deposited metal;
depositing a metal of a different type than the type of metal than the metal of the metal substrate into each trench etched into the photoresist material to form a through metal via;
etching away the photoresist to leave a partial trench surrounding the deposited metal; and
depositing a dielectric material into the partial trench surrounding the deposited metal.

8. A method of fabricating a substrate-on-foil, the method comprising:
etching at least one three-dimensional trench partially through a metal core structure from a top surface thereof;
filling the at least one three-dimensional trench with a dielectric material;
etching a trench into the dielectric material;
depositing a metal of a different type than the type of metal that the metal core structure consists of into each trench etched into the dielectric material; and
griding a back side of the metal core structure until the deposited metal and surrounding dielectric material are exposed.

9. A method of fabricating a substrate-on-foil, the method comprising:
etching at least one three-dimensional trench partially through a metal core structure from a top surface thereof;
filling the at least one three-dimensional trench with a dielectric material;
etching a trench into the dielectric material;
depositing a metal of a different type than the type of metal that the metal core structure consists of into each trench etched into the dielectric material;
etching at least one three-dimensional trench through the metal core structure from a back side thereof until the deposited metal and dielectric material are exposed;
filling the at least one three-dimensional trench with a dielectric material;
etching a trench into the dielectric material until the deposited metal is exposed; and
depositing a metal of a different type than the type of metal that the metal core structure consists of into each trench etched into the dielectric material to form a through metal via.
